(19) United States
(12) Patent Application Publication
(10) Pub. No.: US 2024/0198514 A1
(43) Pub. Date: Jun. 20, 2024

(54) SUBSTRATE CONVEYOR ROBOT AND SUBSTRATE CONVEYING APPARATUS

(71) Applicant: KAWASAKI JUKOGYO KABUSHIKI KAISHA, Kobe-shi, Hyogo (JP)

(72) Inventor: Takeshi SHIBATA, Kobe-shi (JP)

(73) Assignee: KAWASAKI JUKOGYO KABUSHIKI KAISHA, Kobe-shi, Hyogo (JP)

(21) Appl. No.: 18/287,218

(22) PCT Filed: Apr. 6, 2022
(86) PCT No.: PCT/JP2022/017155

§ 371 Date: Oct. 17, 2023

(30) Foreign Application Priority Data
Apr. 23, 2021 (JP) 2021-073430

(51) Int. Cl. B25J 9/06; B25J 9/00; B25J 9/04; B25J 15/00

(52) U.S. Cl. CPC B25J 9/06; B25J 9/0093; B25J 9/043; B25J 15/0019

(57) ABSTRACT

In a substrate conveyor robot, a rotation center of a base link is spaced away from a guide rail cover so that the shortest distance between the guide rail cover and the rotation center of the base link is greater than the maximum turn radius of the base link.

### TECHNICAL FIELD

The present disclosure relates to a substrate conveyor robot and a substrate conveying apparatus, in particular, to a substrate conveyor robot and a substrate conveying apparatus including driving mechanism configured to move a robot arm upward and downward.

### BACKGROUND ART

Conventionally, a substrate conveyor robot and a substrate conveying apparatus including an up-and-down driving mechanism configured to move a robot arm upward and downward are known. Such a substrate conveyor robot and such a substrate conveying apparatus are disclosed in Japanese Patent Laid-Open Publication No. JP 2017-148925, for example.

The Japanese Patent Laid-Open Publication No. JP 2017-148925 discloses a substrate conveyor robot (substrate conveying apparatus) including a robot arm, and an up-and-down driving mechanism configured to move the robot arm upward and downward. The up-and-down driving mechanism of this substrate conveyor robot includes a guide rail extending in an upward/downward direction, and an up-and-down mover configured to move upward and downward along the guide rail. In addition, the substrate conveyor robot includes a guide rail cover is configured to laterally cover an exposed upper part of the guide rail when the up-and-down mover moves downward. The guide rail cover is provided separately from a base link of the robot arm that can turn in a horizontal direction, and is arranged at a position facing the base link in the horizontal direction.

### PRIOR ART

### Patent Document

Patent Document 1: Japanese Patent Laid-Open Publication No. JP 2017-148925

### SUMMARY OF THE INVENTION

However, in the substrate conveyor robot (substrate conveying apparatus) disclosed in the Japanese Patent Laid-Open Publication No. JP 2017-148925, a guide rail cover configured to laterally cover an exposed upper part of the guide rail when the up-and-down mover moves downward is provided separately from the base link of the robot arm that can turn in the horizontal direction, and is arranged at a position facing the base link in the horizontal direction. For this reason, it is conceivable that the guide rail cover may come in contact with the base link when the base link rotates so that a rotation range of the base link may be limited. Consequently, it is desired to provide a substrate conveyor robot and a substrate conveying apparatus capable of preventing a limit of a rotation range of a base link with an upper part of a guide rail being covered by a guide rail cover in a lowered position of an up-and-down mover.

The present disclosure is intended to solve the above problem, and one object of the present disclosure is to provide a substrate conveyor robot and a substrate conveying apparatus capable of preventing a limit of a rotation range of a base link with an upper part of a guide rail being covered by a guide rail cover in a lowered position of an up-and-down mover.

In order to attain the aforementioned object, a substrate conveyor robot according to a first aspect of the present disclosure includes an up-and-down driving mechanism including a stationary part including a guide rail extending in an upward/downward direction, and an up-and-down mover configured to move upward and downward along the guide rail whereby moving the robot arm upward and downward; a guide rail cover arranged on a lateral side of the guide rail to cover an upper part of the guide rail that is exposed toward the lateral side when the up-and-down mover moves downward, and included in the up-and-down mover, wherein the robot arm includes a base link that is connected to the up-and-down mover turnably in a horizontal direction, and is arranged at a height equal to the guide rail cover in the upward/downward direction, and a free-end side link that is connected to the base link turnably in the horizontal direction, and includes one or more arm parts having the free end, and a rotation center of the base link is spaced away from the guide rail cover as viewed from a top side so that the shortest distance between the guide rail cover and the rotation center of the base link is greater than the maximum turn radius of the base link with the upper part of the guide rail being covered by the guide rail cover in a lowered position of the up-and-down mover.

In the substrate conveyor robot according to the first aspect of the present disclosure, as discussed above, a rotation center of the base link is spaced away from the guide rail cover as viewed from a top side so that the shortest distance between the guide rail cover and the rotation center of the base link is greater than the maximum turn radius of the base link with the upper part of the guide rail being covered by the guide rail cover in a lowered position of the up-and-down mover. Accordingly, the guide rail cover can be arranged outside a movement range of the base link with an upper part of the guide rail being covered by the guide rail cover in a lowered position of the up-and-down mover. Consequently, because the guide rail cover does not interfere with the base link, it is possible to prevent a limit of a rotation range of the base link with the upper part of the guide rail being covered by the guide rail cover in a lowered position of the up-and-down mover.

A substrate conveying apparatus according to a second aspect of the present disclosure includes a substrate conveyor robot including a robot arm that includes a holder configured to hold a substrate and arranged in a free end of the robot arm, and an up-and-down driving mechanism that includes a stationary part including a guide rail extending in an upward/downward direction, and an up-and-down mover configured to move upward and downward along the guide rail whereby moving the robot arm upward and downward; a guide rail cover arranged on a lateral side of the guide rail to cover an upper part of the guide rail that is exposed toward the lateral side when the up-and-down mover moves downward, and included in the up-and-down mover; and a robot compartment configured to accommodate the substrate conveyor robot, wherein the robot arm includes a base link that is connected to the up-and-down mover turnably in a horizontal direction, and is arranged at a height equal to the guide rail cover in the upward/downward direction, and a free-end side link that is connected to the base link turnably in the horizontal direction, and includes one or more arm parts having the free end, and a rotation center of the base link is spaced away from the guide rail cover as viewed from a top side so that the shortest distance between the guide rail cover and the rotation center of the base link is greater than the maximum turn radius of the base link with the upper part of the guide rail being covered by the guide rail cover in a lowered position of the up-and-down mover.

In the substrate conveying apparatus according to the second aspect of the present disclosure, as discussed above, a rotation center of the base link is spaced away from the guide rail cover as viewed from a top side so that the shortest distance between the guide rail cover and the rotation center of the base link is greater than the maximum turn radius of the base link with the upper part of the guide rail being covered by the guide rail cover in a lowered position of the up-and-down mover. Accordingly, the guide rail cover can be arranged outside a movement range of the base link with an upper part of the guide rail being covered by the guide rail cover in a lowered position of the up-and-down mover. Consequently, because the guide rail cover does not interfere with the base link, it is possible to provide a substrate conveying apparatus capable of preventing a limit of a rotation range of the base link with the upper part of the guide rail being covered by the guide rail cover in a lowered position of the up-and-down mover.

According to the present disclosure as discussed above, it is possible to prevent a limit of a rotation range of the base link with the upper part of the guide rail being covered by the guide rail cover in a lowered position of the up-and-down mover.

### BRIEF DESCRIPTION OF THE DRAWINGS

FIG. 1 is a plan view showing a semiconductor production apparatus including a substrate conveyor robot according to one embodiment.

FIG. 2 is a schematic side view showing the semiconductor production apparatus including the substrate conveyor robot according to the one embodiment.

FIG. 3 is a plan view showing a base link according to the one embodiment.

FIG. 4 is a cross-sectional view showing the base link, a stationary part, and an up-and-down mover according to the one embodiment.

FIG. 5 is a cross-sectional view taken along a line 300-300 in FIG. 4.

FIG. 6 is a cross-sectional view taken along a line 400-400 in FIG. 4.

FIG. 7 is a cross-sectional view showing the base link, the stationary part, and the up-and-down mover according to the one embodiment when the up-and-down mover moves upward.

FIG. 8 is a side view showing the base link, the stationary part, and the up-and-down mover according to the one embodiment.

FIG. 9 is a cross-sectional view showing a base link, a stationary part, and an up-and-down mover according to a first modified example of the one embodiment.

FIG. 10 is a cross-sectional view showing a base link, a stationary part, and an up-and-down mover according to a second modified example of the one embodiment.

### MODES FOR CARRYING OUT THE INVENTION

Embodiments embodying the present disclosure will be described with reference to the drawings.

### EMBODIMENT

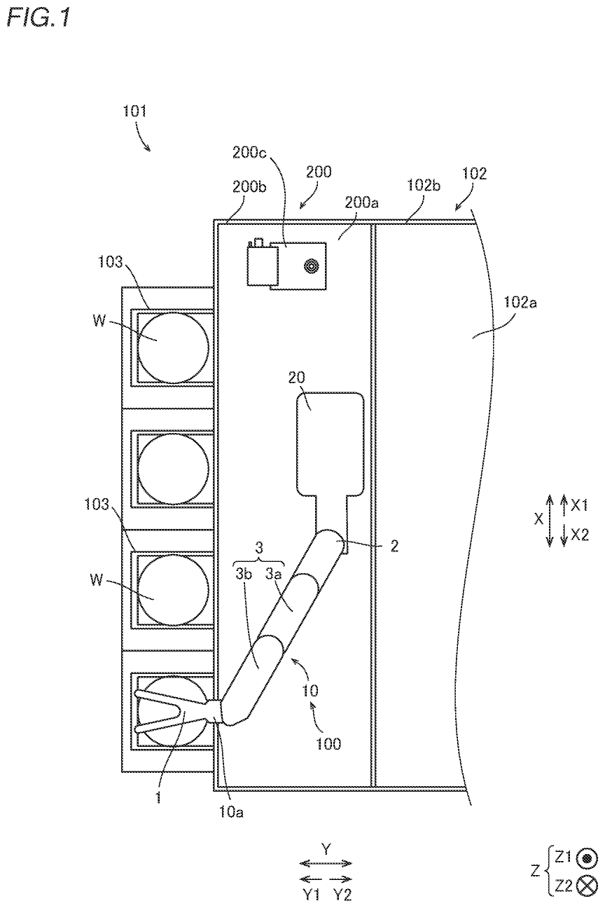

The following description describes configurations of a substrate conveyor robot 100 and a substrate conveying apparatus 200 according to an embodiment with reference to FIGS. 1 to 8.

As shown in FIG. 1, the substrate conveyor robot 100 is used for a semiconductor production apparatus 101 installed in a clean room, for example. The semiconductor production apparatus 101 includes a wafer processing apparatus 102 configured to apply fabrication processes to a semiconductor wafer W, a FOUP 103 as a container for accommodating the wafers W, and a substrate conveying apparatus 200 configured to convey the wafer W between the wafer processing apparatus 102 and the FOUP 103. The substrate conveyor robot 100 is installed in the substrate conveying apparatus 200. The wafer W is an example of a “substrate” in the claims.

The FOUP 103 accommodates wafers W before or after the processes. The wafer processing apparatus 102 can apply the processes such as thermal process, impurity introduction process, thin-film formation process, lithography process, cleaning process, and planarization process to the wafer W.

The wafer processing apparatus 102 includes a processing space formation portion 102b for forming processing space 102a, a processing apparatus main unit (not shown) arranged in the forming processing space 102a configured to apply the processes to the wafer W, and a processing space adjusting device (not shown) configured to adjust an atmosphere gas with which the processing space 102a is filled.

The Substrate conveying apparatus 200 includes a preparation space formation portion 200b for forming preparations space 200a, a substrate conveyor robot 100 arranged in the preparations space 200a, and an aligner 200c arranged in the preparations space 200a and configured to adjust an orientation of the wafer W. Also, the substrate conveying apparatus 200 includes a preparation space adjusting device (not shown) configured to adjust an atmosphere gas with which the preparation space 200a is filled. The preparation space formation portion 200b is an example of a “robot compartment” in the claims.

The preparation space formation portion 200b is formed of a box having a rectangular parallelepiped. The substrate conveyor robot 100 is arranged in substantially central part of a longitudinal direction (X direction) of the preparation space 200a.

The substrate conveyor robot 100 is configured to temporarily convey the wafer W picked up from the FOUP 103 to the aligner 200c when the wafer W is conveyed to the wafer processing apparatus 102 from the FOUP 103. The substrate conveyor robot 100 inserts the wafer W whose orientation is adjusted by the aligner 200c into the wafer processing apparatus 102.

The substrate conveyor robot 100 is a SCARA-type horizontal multi-joint robot. The substrate conveyor robot 100 (substrate conveying apparatus 200) includes a robot arm 10, and an up-and-down driving mechanism 20 to which a base end of the robot arm 10 is connected. The up-and-down driving mechanism 20 is configured to move the robot arm 10 upward and downward.

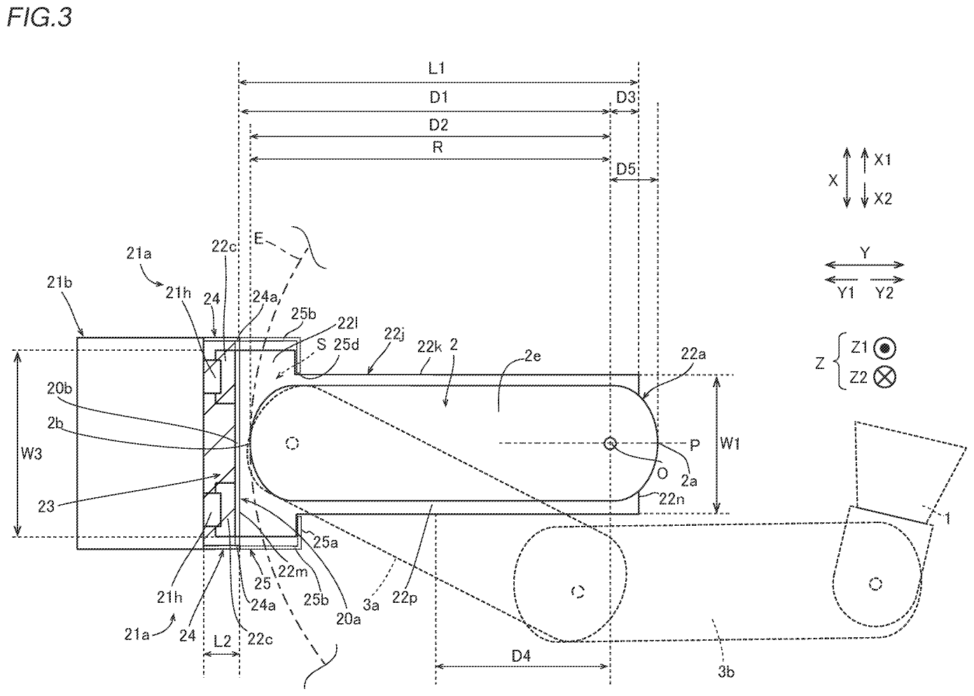

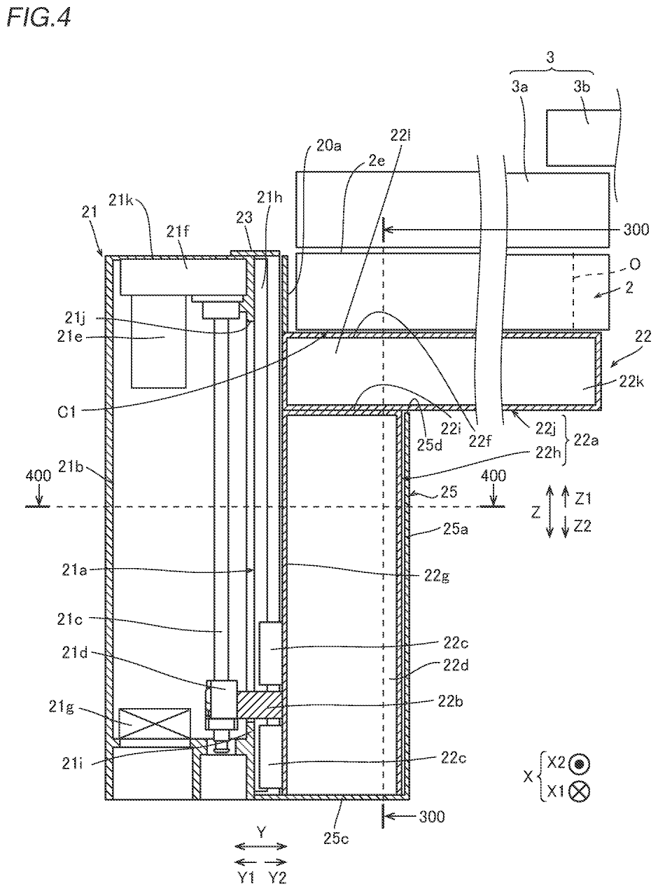

A robot hand (end effector) configured to hold (grasp) the wafer W 1 is arranged in a free end 10a of the robot arm 10. Also, the robot arm 10 includes a base link 2 that is connected to an up-and-down mover 22 discussed later, and can turn in a horizontal direction. The base link 2 is arranged on an upper part of the movable-side case 22a (see FIG. 4). The base link 2 is positioned at the same height as a guide rail cover 20a discussed later in an upward/downward direction. The base link 2 can rotate (turn) about a rotation center O (see FIG. 3). The robot arm 10 includes a free-end side link 3 that is coupled to the base link 2, can turn in the horizontal direction, and includes one or more arm parts one of which includes the free end 10a. Specifically, the free-end side link 3 includes a first link 3a connected to the base link 2, and a second link 3b connected to the first link 3a and the robot hand 1. The robot hand 1 is an example of a “holder” in the claims. The first link 3a and second link 3b are an example of an “arm part” in the claims.

The base link 2 has both end edges having an arc shape and located on both ends in a direction in which the base link 2 extends as viewed from the top side. The both end edges of the base link 2 may have a linear shape as viewed from the top side.

In this embodiment, the free-end side link 3 is positioned at a height different from the guide rail cover 20a in the upward/downward direction (see FIG. 4). Specifically, the first link 3a and the second link 3b are configured to turn on the top side (the Z1 side) of the guide rail cover 20a and a top cover 23 discussed later even when the up-and-down mover 22 moves to the lowest position.

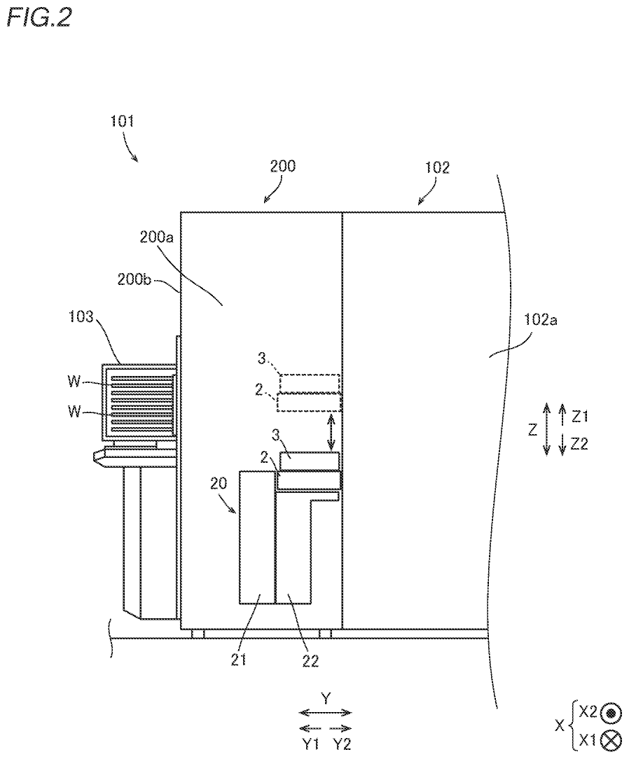

As shown in FIG. 2, the up-and-down driving mechanism 20 includes a stationary part 21 including guide rails 21a (see FIG. 3) extending in an upward/downward direction (Z direction). In addition, the up-and-down driving mechanism 20 includes an up-and-down mover 22 movable upward and downward along the guide rails 21a. In FIG. 2, the base link 2 and the free-end side link 3 that have moved upward are shown by dashed lines. Although the stationary part 21 and the up-and-down mover 22 are illustratively aligned in a Y direction in FIG. 2 as an exemplary arrangement, the present disclosure is not limited to this arrangement.

The up-and-down mover 22 extends in the upward/downward direction. An upper part of the up-and-down mover 22 corresponds to an upper part of the up-and-down driving mechanism 20. When the up-and-down mover 22 moves up and down, a position of the robot hand 1 arranged in the free end 10a of the robot arm 10 is correspondingly moved up and down.

As shown in FIG. 3, the stationary part 21 includes a stationary side case 21b whose external shape is a substantially rectangular parallelepiped (see FIG. 4 elongated in the upward/downward direction (Z direction). In addition, two guide rails 21a are arranged in parallel to and spaced a predetermined interval away from each other in the stationary part 21 on a side where the up-and-down mover 22 is connected.

As shown in FIG. 4, the up-and-down mover 22 includes a movable-side case 22a. A lower case part 22h of the movable-side case 22a discussed later is formed of metal plates forming a top surface and four side surfaces connected to each other, and has an opened bottom. The movable-side case 22a includes a support 22b connected to a nut member 21d discussed later, in stationary side case 21b, and block-shaped movable bodies 22c engaging the guide rails 21a and movable upward and downward. Two movable bodies 22c are arranged in series in each of the two guide rails 21a for moving stability and reliability. In FIG. 4, the robot arm 10 is not sectionally shown but its outline is shown for ease of illustration.

The movable-side case 22a includes the lower case part 22h extending in the upward/downward direction (Z direction). Also, the movable-side case 22a includes an upper case part 22j extending from a guide rail cover 20a side (Y1 side) toward a rotation center O side (Y2 side) of the base link 2 in the Y direction of horizontal directions. The upper case part 22j protrudes from the upper part 22i of the lower case part 22h in a Y2 direction side away from the guide rail 21a. The upper case part 22j includes a part 22k that protrudes from the lower case part 22h, and a part 22l that overlaps the lower case part 22h as viewed from the top side. The upper case part 22j is arranged on a bottom side (Z2 side) of the robot arm to turnably support the robot arm 10 (base link 2). In other words, the movable-side case 22a has an L shape as viewed in the X direction, which is orthogonal to the Y direction, of the horizontal directions. The Y direction and the Y2 direction are examples of “first direction” and “one side of the first direction” in the claims, respectively. The X direction is an example of a “second direction” in the claims. The upper case part 22j is an example of a “support” in the claims.

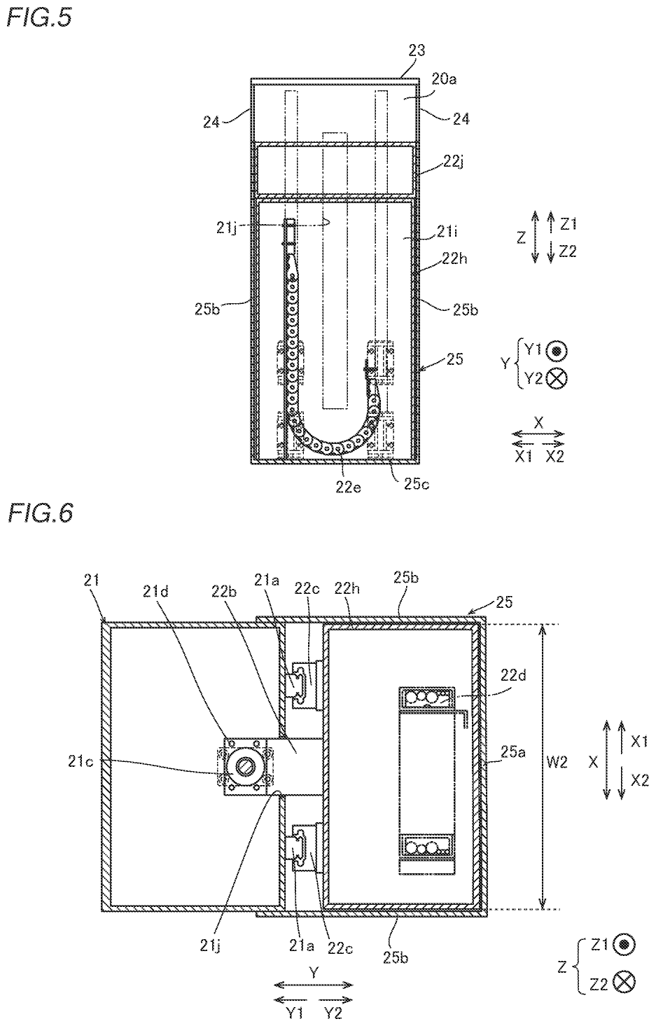

in this embodiment, as shown in FIG. 3, a width W1 of the part 22k of the upper case part 22j in the X direction is smaller than a width W2 (see FIG. 6) of the lower case part 22h in the X direction as viewed from the top side. Also, a width W3 of the part 22l of the upper case part 22j, which overlaps the lower case part 22h, in the X direction is equal to the width W2 of the lower case part 22h. Also, the part 22k of the upper case part 22j protrudes in the Y2 direction from a central part of the part 22l of the upper case part 22j in the X direction. In other words, the upper case part 22j has a T shape as viewed from the top side.

The upper case part 22j and the lower case part 22h are formed separately from each other. The upper case part 22j and the lower case part are connected to each other by fasteners (bolts), welding, etc, and are provided integrally with each other, for example.

A ball screw 21c configured to move the up-and-down mover 22 upward and downward, and the nut member 21d engaging the ball screw 21c to be moved upward and downward in response to rotation of the ball screw 21c are arranged in the stationary side case 21b. Also, an electric motor 21e configured to rotatably drive the ball screw 21c, and a pulley mechanism 21f as a power transmission mechanism configured to transmit a driving force of the electric motor 21e to the ball screw 21c are arranged in the stationary side case 21b. In addition, a fan 21g configured to produce a down air flow in an interior of the stationary side case 21b is arranged in a lower part of the interior of the stationary side case 21b. Accordingly, air inside the stationary side case 21b can be discharged from the lower part to the outside.

The substrate conveyor robot 100 includes a guide rail cover 20a arranged on a lateral side (Y2 side) of the guide rails 21a to cover upper parts 21h of the guide rails 21a that will be exposed in toward the lateral side (toward the Y2 side) when the up-and-down mover 22 moves downward (see FIG. 4).

The stationary side case 21b includes a side wall 211 connected to the up-and-down mover 22 as shown in FIG. 4. The side wall 211 has an opening 21j through which the support 22b passes. The support 22b is moved upward and downward with passing through the opening 21j. The opening 21j is an elongated opening having a length corresponding to the upward and downward movement of the up-and-down mover 22.

The movable-side case 22a has a cable routing area 22d in which power supply and signal cables are routed to servomotors arranged in the base link 2 and the free-end side link 3. For example, the cable routing area 22d is arranged in the lower case part 22h. In addition, the movable-side case 22a (lower case part 22h) includes a cable-route adjuster 22e (see FIG. 5) configured to adjust cable routing when the up-and-down mover 22 moves upward and downward.

A height of a top surface 22f of the movable-side case 22a (upper case part 22j) is dimensioned so that a top surface 2e of the base link 2 substantially agrees with a height of a top surface 21k of the stationary side case 21b when the robot arm 10 is in the lowest position.

In other words, the top surface 22f of the movable-side case 22a (upper case part 22j) is positioned at a position lower by a height (thickness) of the base link 2 than the top surface 21k of the stationary side case 21b when the up-and-down mover 22 has moved to the lowest position. The guide rail cover 20a, and a top cover 23 and a pair of side covers 24, which are discussed later, are provided to prevent exposure of the upper parts 21h of the guide rails 21a, which may bring dust particles, etc. into the preparation space 200a and contaminate the preparation space 200a with the dust particles, etc. when the up-and-down mover 22 moves to the lowest position.

In this embodiment, as shown in FIG. 3, the rotation center O of the base link 2 is spaced away from the guide rail cover 20a as viewed from the top side (Z1 side) so that the shortest distance D1 between the guide rail cover 20a and the rotation center O of the base link 2 is greater than the maximum turn radius R of the base link 2 with the upper part 21h of the guide rail 21a being covered by the guide rail cover 20a in a lowered position of the up-and-down mover 22 (see FIG. 4). In other words, the guide rail cover 20a is arranged outside a movement range of the base link 2.

Specifically, as viewed from the top side (Z1 side), the guide rail cover 20a extends in the X direction. A position of the rotation center O of the base link 2 in the X direction is substantially the same as a position of a center 20b of the guide rail cover 20a in the X direction. That is, the shortest distance D1 between the guide rail cover 20a and the rotation center O of the base link 2 is a distance between the center 20b of the guide rail cover 20a in the X direction and the rotation center O of the base link 2

The base link 2 includes both end edges in a direction in which the base link 2 extends including an edge 2a located close to the rotation center O of the base link 2 as viewed from the top side. Also, the base link includes an edge 2b located away from the rotation center O of the base link 2 of the both end edges in a direction in which the base link 2 extends as viewed from the top side. The maximum turn radius R of the base link 2 is equal to the distance D2 between the rotation center O and the edge 2b of the base link 2. The edge 2a is an example of a “close-side edge” in the claims.

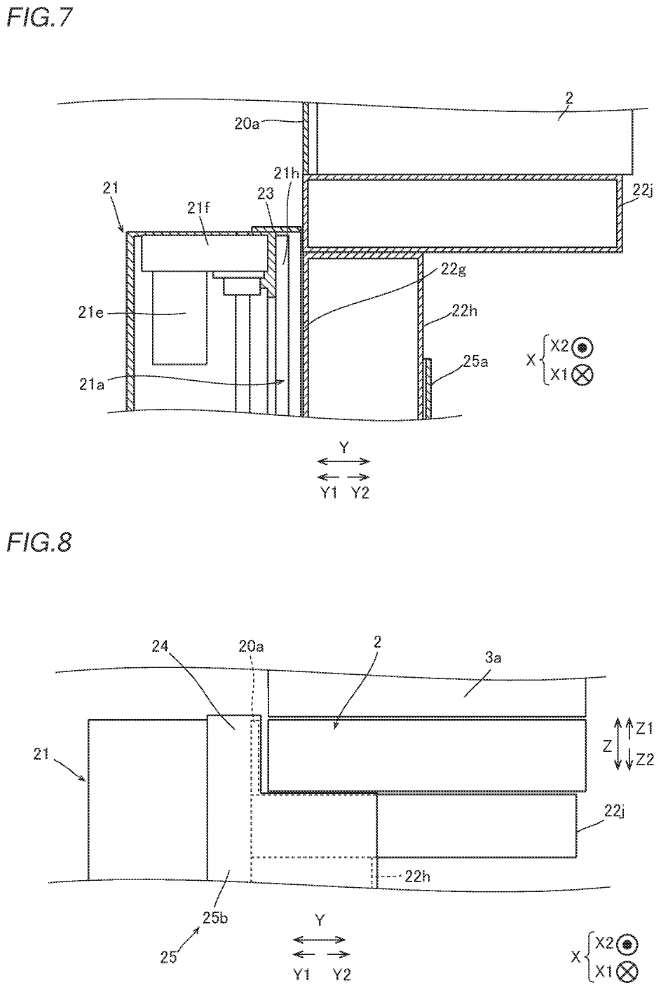

In this embodiment, the shortest distance D1 between the guide rail cover 20a and the rotation center O of the base link 2 is greater than the maximum turn radius R of the base link 2 in a raised position of the up-and-down mover 22 (see FIG. 7). In other words, the up-and-down mover 22 moves upward and downward in the upward/downward direction while keeping the shortest distance D1 greater than the maximum turn radius R. That is, the shortest distance D1 is greater than the maximum turn radius R irrespective of the height of the up-and-down mover 22 in the upward/downward direction.

A gap C1 (see FIG. 4) of approximately 1 to 2 mm is formed between the base link 2 and the movable-side case 22a (upper case part 22j). According to this arrangement, the base link 2 can be smoothly rotated.

In the present embodiment, a length L1 of the upper case part 22j in the Y direction is greater than the shortest distance D1 between the guide rail cover 20a and the rotation center O of the base link 2. Specifically, the difference (L1−D1) between the length L1 of the upper case part 22j and the shortest distance D1 is equal to the shortest distance D3 between the rotation center O and an edge 22n of the upper case part 22j that is opposite to an edge 22m on a guide rail 21a side of the upper case part 22j. The edge 22n extends in the X direction as viewed from the top side.

In this embodiment, the rotation center O of the base link 2 is positioned on a side (Y2 side) opposite to the guide rail 21a with respect to a center 22p of the upper case part 22j in the Y direction as viewed from the top side (Z1 side). Also, the shortest distance D3 between the rotation center O and the edge 22n of the upper case part 22j is smaller than the shortest distance D4 between the rotation center O and the center 22p of the upper case part 22j in the Y direction.

Also, the shortest distance D3 between the rotation center O of the base link 2 and the edge 22n of the upper case part 22j is not greater than a distance D5 between the edge 2a and the rotation center O of the base link 2. Specifically, the shortest distance D3 is smaller than the distance D5. In other words, the edge 2a of the base link 2 protrudes from the edge 22n of the upper case part 22j (toward the Y2 side) in a certain range of a rotational direction of the base link 2 as viewed from the top side. The distance D5 is an example of “the shortest distance between the rotation center and the close-side edge of the base link” in the claims.

Also, in this embodiment, the rotation center O of the base link 2 is spaced away from the guide rail cover 20a so that an outermost edge E of a movement range of the base link 2 overlaps a footprint area S of the lower case part 22h on the rotation center O side of the base link 2 with respect to the guide rail cover 20a as viewed from the top side (Z1 side). In other words, the edge 2b of base link 2 the passes across the footprint area S of the lower case part 22h as viewed from the top side when the base link 2 turns. The edge 2b of the base link 2 passes in proximity to the center 20b of the guide rail cover 20a as viewed from the top side.

The substrate conveyor robot 100 includes the top cover 23 (shaded part in FIG. 3) arranged on a top side (Z2 side) of the upper parts 21h of the guide rails 21a to cover the upper parts 21h of the guide rails 21a. The top cover 23 is arranged on the stationary part 21. The top cover 23 is arranged in proximity to the guide rail cover 20a as viewed from the top side. The top cover 23 is arranged closer to a stationary side case side (Y1 side) than the guide rail cover 20a. In other words, the top cover 23 is arranged out of the movement range of the base link 2 (on Y1 side with respect to the outermost edge E).

In addition, the substrate conveyor robot 100 includes a pair of side covers 24 arranged so that the upper parts 21h of the guide rails 21a are interposed in a lateral direction (in the X direction) between the side covers. The pair of side covers 24 extend in the Y direction as viewed from the top side. Lengths of the pair of side covers 24 in the Y direction are the same size (length L2) as each other. The pair of side covers 24 are arranged on the stationary part 21. The pair of side covers 24 are arranged so that the guide rail cover 20a is interposed between edges 24a of the side covers 24 on the Y2 side. In other words, the pair of side covers 24 are arranged out of the movement range of the base link 2 (on Y1 side with respect to the outermost edge E).

The rotation center O of the base link 2 is positioned at a position corresponding to a center P of the pair of side covers 24 in a direction (X direction) in which the pair of side covers 24 face each other.

Also, as shown in FIG. 4, the stationary side case 21b includes a stationary side cover 25 including a side surface 25a configured to cover the movable-side case 22a (lower case part 22h) from the Y1 side when the up-and-down mover 22 moves to the lowest position, a pair of side surfaces 25b (see FIGS. 5 and 6) configured to cover the movable side case 22a from the X1 side and the X2 side when the up-and-down mover 22 moves to the lowest position, and a bottom surface 25c. The side surface 25a, the pair of side surface 25b and the bottom surface 25c are formed integrally with each other. The stationary side case 21b and the stationary side cover 25 make up parts of a covering means for covering the up-and-down driving mechanism 20. The entire lower case part 22h and the part 22l of the upper case part 22j are enclosed from lateral sides by the pair of side surfaces 25b.

The side surface 25a of the stationary side cover 25 has a cutout part 25d through which the part 22k of the upper case part 22j passes out of (protrudes from) the stationary side cover 25. In other words, the cutout part 25d is formed to prevent interference between the part 22k of the upper case part 22j and the stationary side cover 25.

As shown in FIG. 7, a top of the stationary side cover 25 is opened so that the movable-side case 22a (lower case part 22h) can move into and out of the stationary side cover. The guide rails 21a are hermetically enclosed in space mainly formed by the guide rail cover 20a, a front surface 22g (connection side surface connected to the stationary part 21) of the movable-side case 22a, the top cover 23 and the pair of side covers 24 when the up-and-down mover 22 is located in a lower side (see FIG. 4). Also, the guide rails 21a are hermetically enclosed in space mainly formed by the front surface 22g of the movable-side case 22a, the stationary side cover 25, the top cover 23 and the pair of side covers 24 when the up-and-down mover 22 moves upward and located in an upper side.

Accordingly, surfaces of the guide rails 21a are not exposed over the entire upward and downward stroke of the up-and-down mover 22. As a result, it is possible to maintain a clean atmosphere in the preparation space 200a.

As shown in FIG. 8, the pair of side covers 24 and the stationary side cover 25 (side surfaces 25b) are constructed integrally with each other.

### Advantages of the Embodiment

In this embodiment, the following advantages are obtained.

In this embodiment, as discussed above, in the substrate conveyor robot 100, the rotation center O of the base link 2 is spaced away from the guide rail cover 20a as viewed from the top side so that the shortest distance D1 between the guide rail cover 20a and the rotation center O of the base link 2 is greater than the maximum turn radius R of the base link 2 with the upper part 21h of the guide rail 21a being covered by the guide rail cover 20a in a lowered position of the up-and-down mover 22. Accordingly, the guide rail cover 20a can be arranged outside a movement range of the base link 2 with an upper part 21h of the guide rail 21a being covered by the guide rail cover 20a in a lowered position of the up-and-down mover 22. Consequently, because the guide rail cover 20a does not interfere with the base link 2, it is possible to prevent a limit of a rotation range of the base link 2 with the upper part 21h of the guide rail 21a being covered by the guide rail cover 20a in a lowered position of the up-and-down mover 22.

In this embodiment, as discussed above, the shortest distance D1 between the guide rail cover 20a and the rotation center O of the base link 2 is greater than the maximum turn radius R of the base link 2 in a raised position of the up-and-down mover 22. Accordingly, it is possible to prevent a limit of a rotation range of the base link 2 limited by the guide rail cover 20a even when the up-and-down mover 22 moves upward.

In this embodiment, as discussed above, the up-and-down mover 22 includes an upper case part 22j (support) that extends from a guide rail cover 20a side of the up-and-down mover toward the rotation center O of the base link 2 in the Y direction (first direction) of horizontal directions as viewed from the top side, and is arranged on a bottom side of the robot arm to turnably support the robot arm 10. In addition, a length L1 of the upper case part 22j in the Y direction is greater than the shortest distance D1 between the guide rail cover 20a and the rotation center O of the base link 2. Because the length L1 of the upper case part 22j is greater than the shortest distance D1, it is easily possible to prevent contact (interference) between the base link 2, which is supported by the upper case part 22j, and the guide rail cover 20a.

In this embodiment, as discussed above, the up-and-down mover 22 includes a movable-side case 22a having an L shape as viewed in the X direction (second direction) of the horizontal directions orthogonal to the Y direction (first direction), and including a lower case part 22h that extends in the upward/downward direction, and the upper case part 22j (support) which is arranged on the bottom side of the robot arm to turnably support the robot arm 10 and protrudes from an upper part 22i of the lower case part 22h toward the Y1-direction side (one side of the first direction) of the horizontal directions away from the guide rail 21a. In addition, the rotation center O of the base link 2 is positioned on a side opposite to the guide rail 21a with respect to a center 22p of the upper case part 22j in the Y direction as viewed from the top side. Accordingly, while contact (interference) between the base link 2 and the guide rail cover 20a is prevented, a movement range (maximum turn radius R) of the base link 2 can be increased as compared with a case in which the rotation center O of the base link 2 is positioned on a guide rail 21a side with respect to the center 22p of the upper case part 22j. Also, because the movable-side case 22a having an L shape as viewed in the X direction, while increasing a distance (shortest distance D1) between the rotation center O of the base link 2 and the guide rail cover 20a, the protruding and extending upper case part 22j can reduce a footprint area of the lower case part 22h as compared with a case in which a lower case part 22h has a length is equal to the upper case part 22j so that a movable-side case 22a has a rectangular shape as viewed in the X direction.

Also, in this embodiment, as discussed above, the rotation center O of the base link 2 is spaced away from the guide rail cover 20a so that an outermost edge E of a movement range of the base link 2 overlaps a footprint area S of the lower case part 22h on the rotation center O side of the base link 2 with respect to the guide rail cover 20a as viewed from the top side. Accordingly, the movement range (maximum turn radius R) of the base link 2 can be increased as compared with a case in which an outermost edge E of a movement range of the base link 2 is located on the rotation center O side with respect to the guide rail cover 20a without overlapping a footprint area S of the lower case part 22h.

In this embodiment, as discussed above, a width W1 of a part 22k of the upper case part 22j that protrudes from the lower case part 22h in the X direction (second direction) is smaller than a width W2 of the lower case part 22h in the X direction as viewed from the top side. Accordingly, because the part 22k of the upper case part 22j can be smaller, space around the upper case part 22j (part 22k) can be larger than a case in which the width W1 is not smaller than the width W2.

In this embodiment, as discussed above, the base link 2 includes both end edges in a direction in which the base link 2 extends including an edge 2a (close-side edge) located close to the rotation center O as viewed from the top side. In addition, the shortest distance D3 between the rotation center O and an edge 22n of the upper case part 22j opposite to a guide rail 21a side edge 22m of the upper case part 22j is not greater than the shortest distance D5 between the rotation center O and the edge 2a of the base link 2 as viewed from the top side. Accordingly, a protrusion amount of the upper case part 22j (part 22k) can be smaller than a case in which the shortest distance D3 is greater than the distance D5.

In this embodiment, as discussed above, the free-end side link 3 is positioned at a height different from the guide rail cover 20a in the upward/downward direction. Accordingly, it is easily possible to prevent contact (interference) between the free-end side link 3 and the guide rail cover 20a when the free-end side link 3 turns in a horizontal direction. Consequently, it is possible to prevent a limit of a movement range of the free-end side link 3 limited by the guide rail cover 20a.

Also, in this embodiment, as discussed above, in the substrate conveying apparatus 200, the rotation center O of the base link 2 is spaced away from the guide rail cover 20a as viewed from the top side so that the shortest distance D1 between the guide rail cover 20a and the rotation center O of the base link 2 is greater than the maximum turn radius R of the base link 2 with the upper part 21h of the guide rail 21a being covered by the guide rail cover 20a in a lowered position of the up-and-down mover 22. Accordingly, the guide rail cover 20a can be arranged outside a movement range of the base link 2 with an upper part 21h of the guide rail 21a being covered by the guide rail cover 20a in a lowered position of the up-and-down mover 22. Consequently, because the guide rail cover 20a does not interfere with the base link 2, it is possible to provide a substrate conveying apparatus 200 capable of preventing a limit of a rotation range of the base link 2 with the upper part 21h of the guide rail 21a being covered by the guide rail cover 20a in a lowered position of the up-and-down mover 22.

### Modified Embodiment

Note that the embodiment disclosed this time must be considered as illustrative in all points and not restrictive. The scope of the present invention is not shown by the above description of the embodiments but by the scope of claims for patent, and all modifications or modified examples within the meaning and scope equivalent to the scope of claims for patent are further included.

While the example in which the upper case part 22j and the lower case part 22h are formed separately from each other has been shown in the aforementioned embodiment, the present disclosure is not limited to this. The upper case part and the lower case part may not be formed separately from each other.

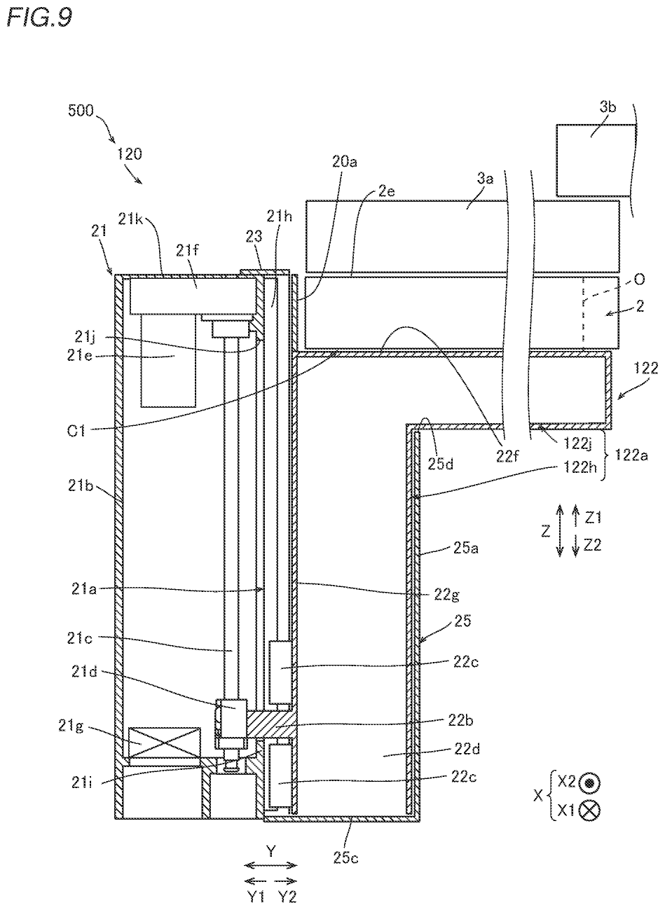

Specifically, as shown in FIG. 9, an up-and-down mover 122 of an up-and-down driving mechanism 120 of a substrate conveyor robot 500 includes a movable-side case 122a including an upper case part 122j and a lower case part 122h. The upper case part 122j and the lower case part 122h are formed not separately from each other but continuously from one to another. In other words, the movable-side case 122a is formed of one case having an L shape as viewed in a lateral direction (X direction). The upper case part 122j is an example of a “support” in the claims.

While the example in which the movable-side case 22a has an L shape as viewed in a lateral direction (X direction) has been shown in the aforementioned embodiment, the present disclosure is not limited to this. The movable-side case may not have an L shape as viewed in a lateral direction (X direction).

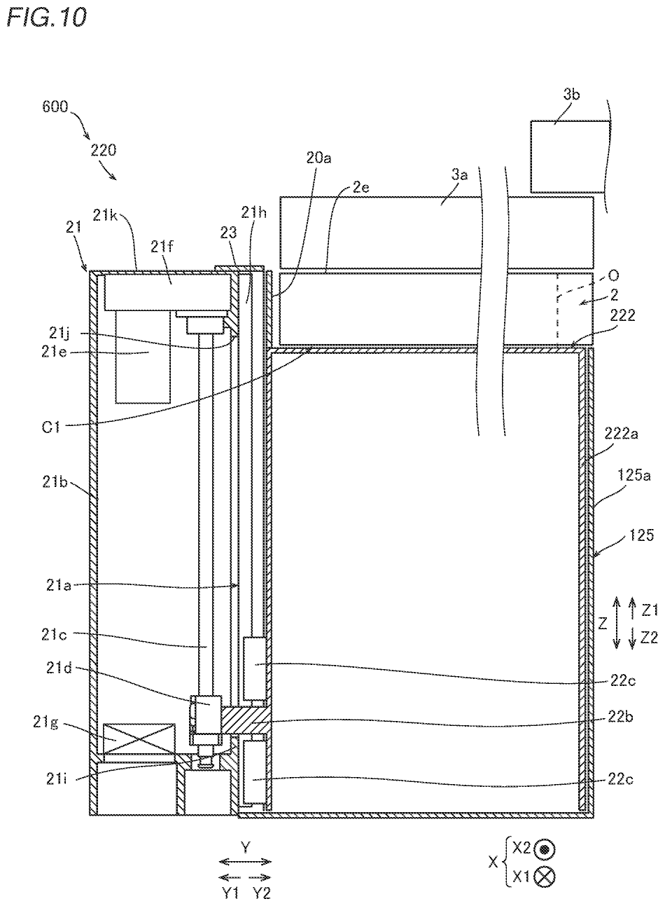

For example, as shown in FIG. 10, an up-and-down mover 222 of an up-and-down driving mechanism 220 of a substrate conveyor robot 600 includes a movable-side case 222a having quadrangular shape (rectangular shape) as viewed from the X1-direction side. In this case, a side surface 125a of a stationary side cover 125 arranged to cover the movable-side case 222a from the Y2-direction side is positioned on the Y2-direction side with respect to the rotation center O of the base link 2. While the example in which the movable-side case 222a is formed of one case similar to FIG. 9 has been shown in FIG. 10, the upper case part and the lower case may be formed separately from each other as described in the aforementioned embodiment. In other words, in this case, the lower case part has the same length as the upper case part in the Y direction. The movable-side case 222a is an example of a “support” in the claims.

While the example in which a width W1 of a part 22k of the upper case part 22j that protrudes from the lower case part 22h in the X direction is smaller than a width W2 of the lower case part 22h in the X direction as viewed from the top side has been shown in the aforementioned embodiment, the present disclosure is not limited to this. The width W1 may be not smaller than the width W2.

While the example in which the shortest distance D3 between the edge 22n of the upper case part 22j and the rotation center O of the base link 2 is not greater than the distance D5 (the shortest distance) between the edge 2a (close-side edge) of the base link 2 and the rotation center O has been shown in the aforementioned embodiment, the present disclosure is not limited to this. The shortest distance D3 may be greater than the distance D5.

### DESCRIPTION OF REFERENCE NUMERALS

1: robot hand (holder)
2: base link
2a: edge (close-side edge)
3: free-end side link
3a: first link (arm part)
3b: second link (arm part)
10: robot arm
10a: free end
20: up-and-down driving mechanism
20a: guide rail cover
21: stationary part
21a: guide rail
21h: upper part
22, 122, 222: up-and-down mover
22a, 122a: movable-side case
22h, 122h: lower case part
22i: upper part
22j, 122j: upper case part (support)
22k: part (protruding part)
22m: edge (edge on guide rail side)
22n: edge (edge on side opposite to edge of guide rail side)
22p: center
100, 500: substrate conveyor robot
200, 600: substrate conveying apparatus
200b: preparation space formation portion (robot compartment)
222a: movable-side case (support)
D1: shortest distance
D3: shortest distance (shortest distance between edge of upper case part and rotation center)
D5: distance (shortest distance between close-side edge and rotation center)
E: outermost edge
L1: length
O: rotation center
R: maximum turn radius
S: footprint area
W: wafer (substrate)
W1: width (width of protruding part)
W2: width (width of lower case part)
X: direction (second direction)
Y: direction (first direction)
Y2: direction (one side of first direction)

1. A substrate conveyor robot comprising:
a robot arm including a holder configured to hold a substrate and arranged in a free end of the robot arm;
an up-and-down driving mechanism including a stationary part including a guide rail extending in an upward/downward direction, and an up-and-down mover configured to move upward and downward along the guide rail whereby moving the robot arm upward and downward;
a guide rail cover arranged on a lateral side of the guide rail to cover an upper part of the guide rail that is exposed toward the lateral side when the up-and-down mover moves downward, and included in the up-and-down mover, wherein
the robot arm includes a base link that is connected to the up-and-down mover turnably in a horizontal direction, and is arranged at a height equal to the guide rail cover in the upward/downward direction, and a free-end side link that is connected to the base link turnably in the horizontal direction, and includes one or more arm parts having the free end, and
a rotation center of the base link is spaced away from the guide rail cover as viewed from a top side so that the shortest distance between the guide rail cover and the rotation center of the base link is greater than the maximum turn radius of the base link with the upper part of the guide rail being covered by the guide rail cover in a lowered position of the up-and-down mover.

2. The substrate conveyor robot according to claim 1, wherein the shortest distance between the guide rail cover and the rotation center of the base link is greater than the maximum turn radius of the base link in a raised position of the up-and-down mover.

3. The substrate conveyor robot according to claim 1, wherein
the up-and-down mover includes a support that extends from a guide rail cover side of the up-and-down mover toward the rotation center of the base link in a first direction of horizontal directions as viewed from the top side, and is arranged on a bottom side of the robot arm to turnably support the robot arm; and
a length of the support in the first direction is greater than the shortest distance between the guide rail cover and the rotation center of the base link.

4. The substrate conveyor robot according to claim 3, wherein
the up-and-down mover includes a movable-side case having an L shape as viewed from a second direction of the horizontal directions orthogonal to the first direction, and including a lower case part that extends in the upward/downward direction, and an upper case part that protrudes from an upper part of the lower case part toward one side of the first direction of the horizontal directions away from the guide rail and includes the support, which is arranged on the bottom side of the robot arm to turnably support the robot arm; and
the rotation center of the base link is positioned on a side opposite to the guide rail with respect to a center of the upper case part in the first direction as viewed from the top side.

5. The substrate conveyor robot according to claim 4, wherein the rotation center of the base link is spaced away from the guide rail cover so that an outermost edge of a movement range of the base link overlaps a footprint area of the lower case part on a rotation center side of the base link with respect to the guide rail cover as viewed from the top side.

6. The substrate conveyor robot according to claim 4, wherein a width of a part of the upper case part that protrudes from the lower case part in the second direction is smaller than a width of the lower case part in the second direction as viewed from the top side.

7. The substrate conveyor robot according to claim 4, wherein
the base link includes both end edges in a direction in which the base link extends including a close-side edge located close to the rotation center as viewed from the top side; and
the shortest distance between the rotation center and an edge of the upper case part opposite to a guide-rail-side edge of the upper case part is not greater than the shortest distance between the rotation center and the close-side edge of the base link as viewed from the top side.

8. The substrate conveyor robot according to claim 1, wherein the free-end side link is positioned at a height different from the guide rail cover in the upward/downward direction.

9. A substrate conveying apparatus comprising:
a substrate conveyor robot including a robot arm that includes a holder configured to hold a substrate and arranged in a free end of the robot arm, and an up-and-down driving mechanism that includes a stationary part including a guide rail extending in an upward/downward direction, and an up-and-down mover configured to move upward and downward along the guide rail whereby moving the robot arm upward and downward;
a guide rail cover arranged on a lateral side of the guide rail to cover an upper part of the guide rail that is exposed toward the lateral side when the up-and-down mover moves downward, and included in the up-and-down mover; and
a robot compartment configured to accommodate the substrate conveyor robot, wherein
the robot arm includes a base link that is connected to the up-and-down mover turnably in a horizontal direction, and is arranged at a height equal to the guide rail cover in the upward/downward direction, and a free-end side link that is connected to the base link turnably in the horizontal direction, and includes one or more arm parts having the free end, and
a rotation center of the base link is spaced away from the guide rail cover as viewed from a top side so that the shortest distance between the guide rail cover and the rotation center of the base link is greater than the maximum turn radius of the base link with the upper part of the guide rail being covered by the guide rail cover in a lowered position of the up-and-down mover.
